(19) United States
(12) Patent Application Publication
(10) Pub. No.: US 2012/0307456 A1
(43) Pub. Date: Dec. 6, 2012

(54) NETWORK CABINET

(75) Inventor: XIANG CAO, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/331,711

(22) Filed: Dec. 20, 2011

(30) Foreign Application Priority Data
Jun. 3, 2011 (CN) 201110148523.7

(51) Int. Cl. H05K 5/00

(52) U.S. Cl. 361/724

(57) ABSTRACT

A network cabinet includes a door, a sensor, a multifunctional button, and a rotating display device; the door is installed in the network cabinet, the rotating display device is installed in the door, and 360 degree rotation is possible. The user may control an angle of rotation as required, either by selecting on each occasion, or automatically, to facilitate an exchange of data with the equipment in the network cabinet, by means of a touch screen oriented to suit the user.

### BACKGROUND

1. Technical Field

The present disclosure generally relates to network cabinets, particular to a network cabinet assembled with a rotating display device.

2. Description of Related Art

Network cabinets may include internally mounted display devices and keyboards. However, the inner space may not be enough to provide comfortable access and restricted available space may reduce the functionality of the keyboard and the display devices, and prevent adjustability when being used. Such features as full functionality and adjustability can be realized if the user carries an independent keyboard and display device to the network server for temporary connection and use.

Therefore, there is room for improvement within the art

### BRIEF DESCRIPTION OF THE DRAWINGS

Many aspects of the exemplary network cabinet can be better understood with reference to the following drawings. The components in the various drawings are not necessarily drawn to scale, the emphasis instead being placed upon clearly illustrating the principles of the exemplary network cabinet. Moreover, in the drawings, like reference numerals designate corresponding parts throughout the diagrams.

FIG. 1 is an isometric view of a display device in a network cabinet according to an exemplary embodiment.

FIG. 2 is an isometric view of the display device door shown in FIG. 1 in an open position.

FIG. 3 is another isometric view of the of network cabinet shown in FIG. 2 in an open position and with the orientation of the display device changed.

FIG. 4 is a block diagram of a modular circuit for the display device shown in FIGS. 1 through 3.

FIG. 5 is an isometric view of a display device in a network cabinet according to another exemplary embodiment.

### DETAILED DESCRIPTION

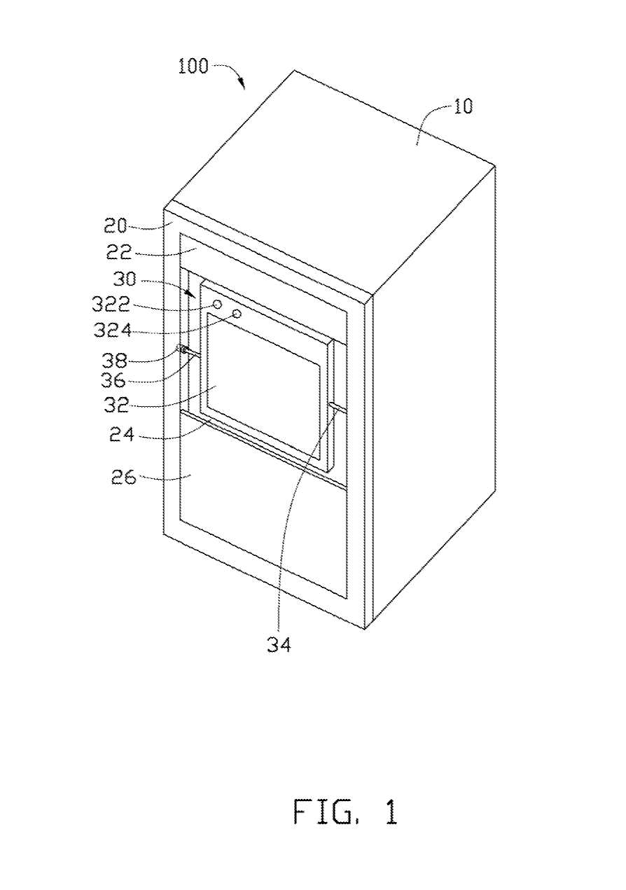

FIG. 1 shows an exemplary network cabinet 100 including a cabinet body 10 for receiving network devices, a door 20, and a display device 30 installed into the door 20.

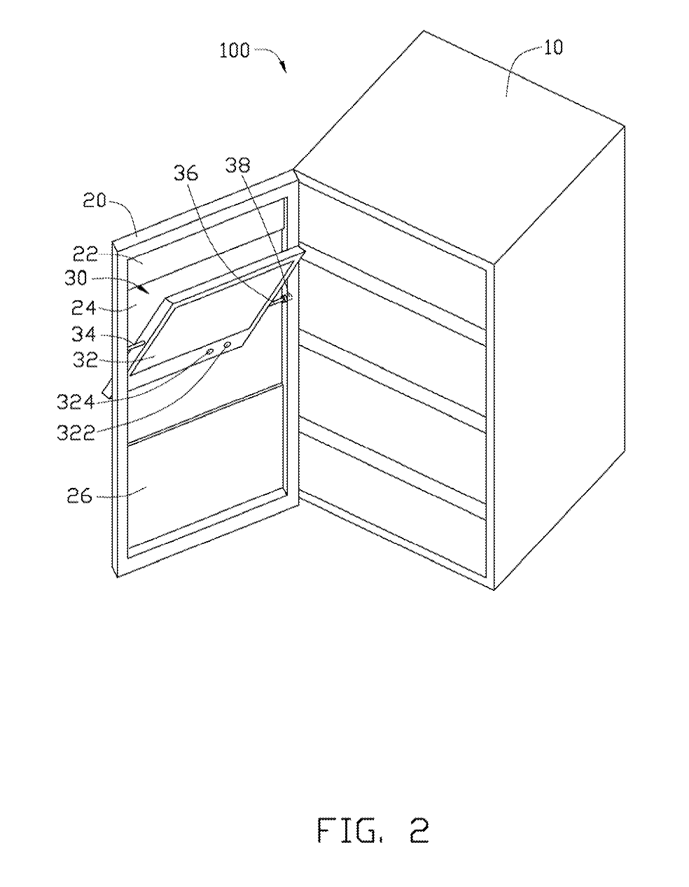

Referring to FIG. 2, the door 20 is pivotably connected to a side flange of the cabinet body 10. The door 20 has a cutout 24 defined for receiving the display device 30, and a simple physical or electronic sensor (not shown) to determine the open or closed status of the door 20 mounted therein. In another embodiment, the sensor (not shown) may be mounted in the cabinet body 10.

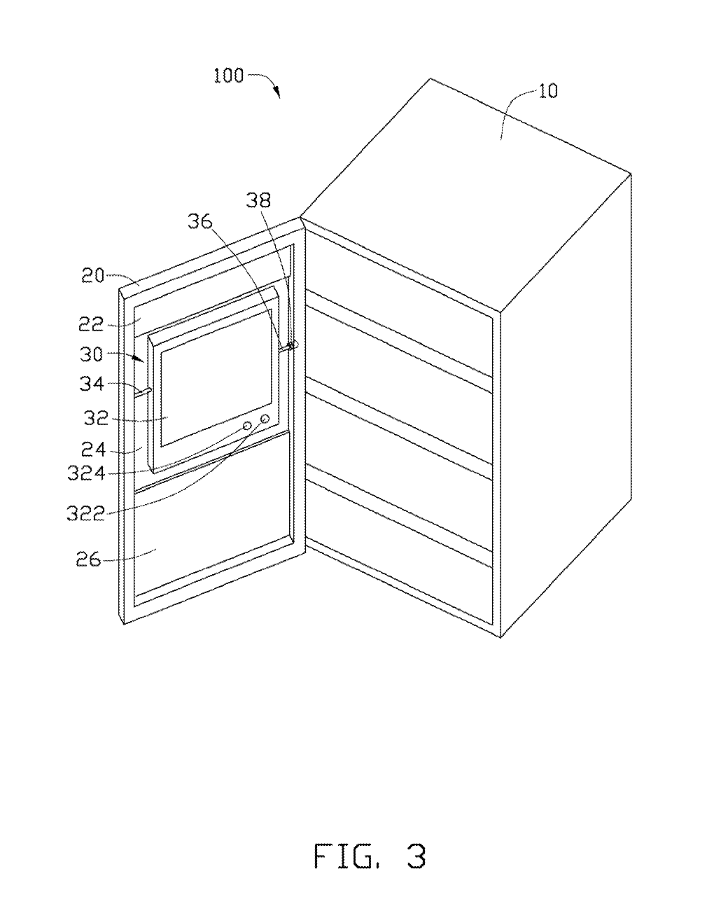

The display device 30 includes a full-featured touch screen display 32 rotatably received in the cutout 24. The use of a touch screen display 32 eliminates the need for a separate or independent keyboard. The rotatability of the display device 30 allows a user to position the rotating display device 30 at an angle which is comfortable for user input and, in the embodiment, user input can be achieved whether the door 20 is open or shut. The rotating display device 30 further includes a display 32 to each side of which a shaft (driving shaft 36 on one side and shaft 34 on the other side) is medially connected, to both support the display 32 and allow it to be rotated. The drive shaft 36 is connected to a motor 38. The motor 38 is electrically powered by a power supply 37 and mounted inside one side of the door 20. The motor 38 may be a stepper motor and may be equipped with gears. A switch 322 and a button 324 are mounted on the touch screen display 32 at one side. The rotating display device 30 can be placed into the cutout 24, the shaft 34 and the drive shaft 36 connecting to the two opposite sides of the touch screen display 32 and supporting it. The turning shaft of the motor 38 is connected to the drive shaft 36, and the motor 38 can drive the shaft 36 to rotate and thus the device 30 is rotated. The touch screen display 32 can be rotated to any angle. When the desired orientation is reached, the motor 38 stops and the display 30 can be held firmly in place by the motor 38 (see FIGS. 2 and 3).

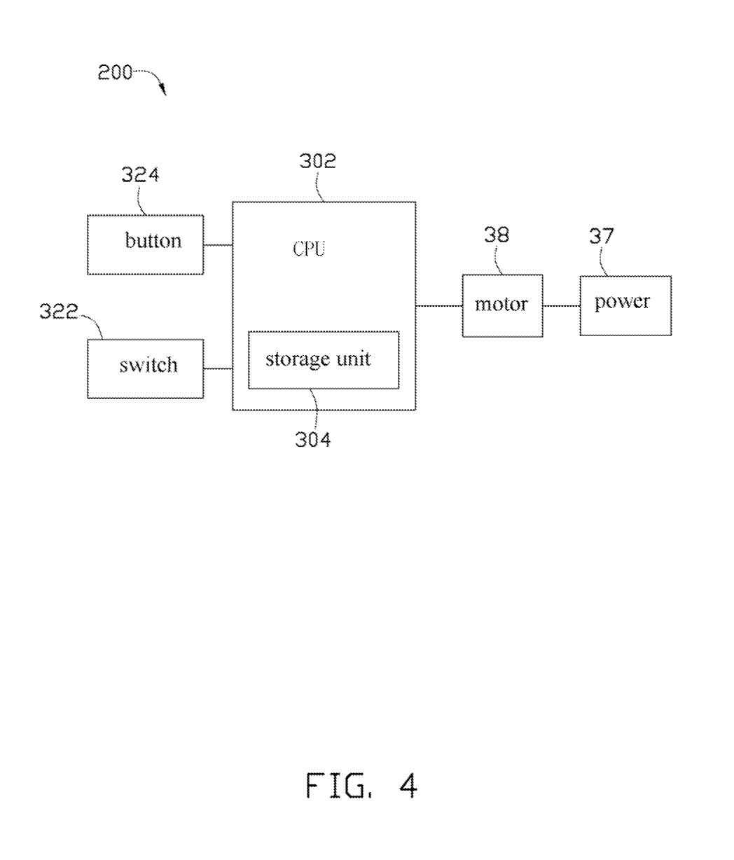

Referring to FIG. 4, the network cabinet 100 also includes a modular circuit 200 for controlling the rotation of the touch screen display 32. The modular circuit includes a central processing unit (CPU) and a storage unit 304 in combination connecting the button 324 and the switch 322. The modular circuit is also connected to the sensor (not shown) in the door 20 and the modular circuit can withhold any activation signal or instruction to the motor 38 if the sensor indicates that the door 20 is in a closed state. The storage unit 304 stores rotational procedures for the display 30. When the button 324 is pressed, the CPU 302 can be triggered to exchange data with the storage unit 304 and send a signal for controlling the working of the motor 38. The rotational procedures in the storage unit 304 may include instructions for certain automatic operations to be carried out as soon as the sensor in the door 20 indicates that the door 20 is no longer in a closed state, for example, the motor 38 may be signaled or instructed to automatically rotate the touch screen display 32 into the last known orientation before a “close door” signal was given by a user on a previous occasion through the button 324.

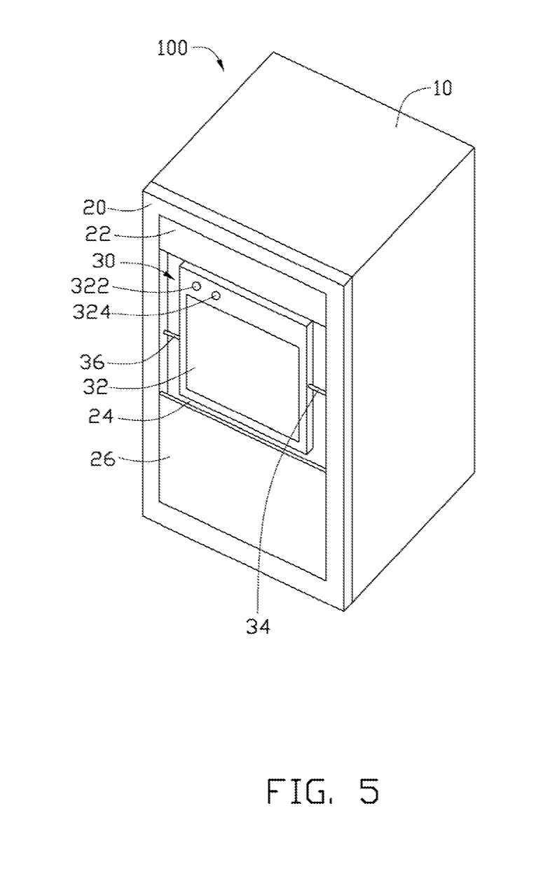

Referring to FIG. 5, the present disclosure include another embodiment, which does not need a power supply 37, and has no motor 38. In that embodiment, everything is done manually, the supporting shafts (34, 36) having high-friction material at their ends so that once turned by hand to a certain angle, the friction material will keep the screen display 32 in that position

Although numerous characteristics and advantages of the exemplary embodiments have been set forth in the foregoing description, together with details of the structures and functions of various embodiments, the disclosure is illustrative only, and changes may be made in detail, especially in the matters of shape, size, and arrangement of parts within the principles of the exemplary invention to the full extent indicated by the broad general meaning of the terms in which the appended claims are expressed.

What is claimed is:

1. A network cabinet, comprising:
a cabinet body;
a door; and
a display device mounted in the door, the display device being capable of rotating at any angle relative to the door.

2. The network cabinet as claimed in claim 1, wherein the display device includes a touch screen display, a shaft, a drive shaft, and a motor, the touch screen display is rotatable received in the cutout, and the shaft and the drive shaft rotatably connects to two opposite sides of the touch screen display.

4. The network cabinet as claimed in claim 2, wherein the motor is installed along one side of door.

5. The network cabinet as claimed in claim 2, wherein the touch screen display has switches and buttons, the switches and buttons used for separately opening and controlling the touch screen display.

6. The network cabinet as claimed in claim 2, wherein the network cabinet also includes a modular circuit for controlling rotation of the touch screen display, the modular circuit includes a central processing unit and a storage unit in combination with, and connecting the button and the switch.

7. The network cabinet as claimed in claim 6, wherein the storage unit stores a rotation procedure for the display, and when pressing the button, the CPU can be triggered to operate with the storage unit and send a controlling signal to the motor for controlling its operation.
